(19) United States
(12) Patent Application Publication
(10) Pub. No.: US 2024/0099017 A1
(43) Pub. Date: Mar. 21, 2024

(54) SEMICONDUCTOR DEVICE

(71) Applicant: SAMSUNG ELECTRONICS CO., LTD., Suwon-si (KR)

(72) Inventors: Jungmin PARK, Suwon-si (KR); Hanjin LIM, Suwon-si (KR); Hyungsuk JUNG, Suwon-si (KR)

(21) Appl. No.: 18/141,738

(22) Filed: May 1, 2023

(30) Foreign Application Priority Data
Sep. 19, 2022 (KR) 10-2022-0118161

(51) Int. Cl. H10B 53/30

(52) U.S. Cl. CPC H10B 53/30

(57) ABSTRACT

A semiconductor device includes a plurality of memory cells each including a cell transistor and a memcitor connected to the cell transistor, and the memcitor includes an information storage layer including a ferroelectric material, a first electrode and a second electrode connected to both ends of the information storage layer, a fixed layer stacked on the information storage layer and including a paraelectric material or an antiferroelectric material, and a third electrode connected to the fixed layer without contacting the information storage layer.

### CROSS-REFERENCE TO RELATED APPLICATION

This application is based on and claims priority under 35 U.S.C. § 119 to Korean Patent Application No. 10-2022-0118161, filed on Sep. 19, 2022, in the Korean Intellectual Property Office, the disclosure of which is incorporated by reference herein in its entirety.

### BACKGROUND

### 1. Field

Embodiments relate to a semiconductor device, and more particularly, to a semiconductor device having a plurality of memory cells.

As used herein, the term “memcitor” refers to generally to a memory device that includes a capacitor, which is volatile, and that includes memory functions such that polarizations or charges may be changed by applying an electric field in a non-volatile manner.

### 2. Description of the Related Art

In accordance with the rapid development of the electronics industry and user demand, electronic devices are becoming more miniaturized and multifunctional, and larger in capacity. Highly integrated and large capacity memory cells are desired for a semiconductor device that is used for an electronic device.

### SUMMARY

Embodiments are directed to a semiconductor device including a plurality of memory cells each including a cell transistor and a memcitor connected to the cell transistor. The memcitor includes an information storage layer including a ferroelectric material, a first electrode and a second electrode connected to both ends of the information storage layer, a fixed layer stacked on the information storage layer and including a paraelectric material or an antiferroelectric material, and a third electrode connected to the fixed layer without contacting the information storage layer.

According to an embodiment, there is provided a semiconductor device including a substrate, a plurality of word lines extending on the substrate in a first direction and apart from one another in a second direction perpendicular to the first direction, a plurality of bit lines extending on the substrate in the second direction and apart from one another in the first direction, and a plurality of memory cells arranged between the word lines and the bit lines and each of the memory cells including a cell transistor and a memcitor connected to the cell transistor. The memcitor includes an information storage layer including a ferroelectric material, a first electrode and a second electrode connected to both ends of the information storage layer, a fixed layer that does not contact the first electrode and the second electrode, that is stacked on the information storage layer, and that includes a paraelectric material or an antiferroelectric material, and a third electrode connected to the fixed layer without contacting the information storage layer. A gate, a source, and a drain of a cell transistor of each of the plurality of memory cells is connected to one of the plurality of word lines, one of the plurality of bit lines, and the second electrode of the memcitor

According to another embodiment, there is provided a semiconductor device including a substrate, a plurality of word lines extending on the substrate in a first direction and apart from one another in a second direction perpendicular to the first direction, a plurality of bit lines extending on the substrate in the second direction and apart from one another in the first direction, and a plurality of memory cells arranged between the word lines and the bit lines and each including a cell transistor and a memcitor connected to the cell transistor. The memcitor includes an information storage layer including a ferroelectric material with an orthorhombic phase, a first electrode and a second electrode connected to both ends of the information storage layer, a fixed layer that does not contact the first electrode and the second electrode, that is stacked on the information storage layer, and that includes a paraelectric material or an antiferroelectric material with an orthorhombic phase, and a third electrode connected to the fixed layer without contacting the information storage layer. A gate, a source, and a drain of a cell transistor of each of the plurality of memory cells is connected to one of the plurality of word lines, one of the plurality of bit lines, and the second electrode of the memcitor.

### BRIEF DESCRIPTION OF THE DRAWINGS

Features will become apparent to those of skill in the art by describing in detail exemplary embodiments with reference to the attached drawings in which:

FIG. 1 is an equivalent circuit diagram of a semiconductor device according to an embodiment;

FIGS. 2A and 2B are views describing a configuration and operating principle of a memcitor included in a memory cell of a semiconductor device according to an embodiment;

FIGS. 3A to 3D are views describing an operation of a memcitor included in a memory cell of a semiconductor device according to an embodiment;

FIGS. 4A and 4B are graphs describing an operation of a memcitor included in a memory cell of a semiconductor device according to an embodiment;

FIGS. 5A to 5C are views describing configurations of memcitors included in memory cells of a semiconductor device according to embodiments;

FIG. 6 is a schematic plan layout describing main components of a semiconductor device according to an embodiment;

FIGS. 7A and 7B are cross-sectional views illustrating a semiconductor device according to an embodiment;

FIGS. 8A and 8B are cross-sectional views illustrating a semiconductor device according to an embodiment;

FIG. 9 is a layout diagram illustrating a semiconductor device according to an embodiment, and FIG. 10 is a cross-sectional view taken along the lines X1-X1′ and Y1-Y1′ of FIG. 9;

FIG. 11 is an equivalent circuit diagram of a semiconductor device according to an embodiment; and

FIG. 12 is a perspective view illustrating a semiconductor device according to an embodiment.

### DETAILED DESCRIPTION

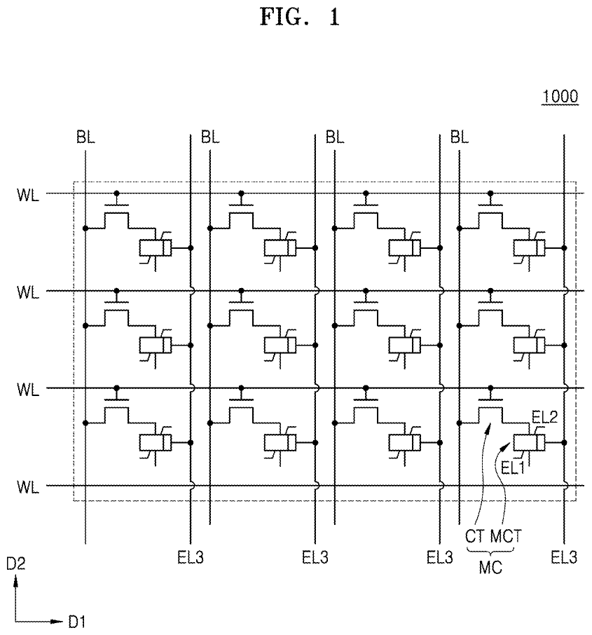

FIG. 1 is an equivalent circuit diagram of a semiconductor device 1000 according to an embodiment.

Referring to FIG. 1, the semiconductor device 1000 may include a plurality of word lines WL extending in a first direction D1 and apart from one another in a second direction D2 perpendicular to the first direction D1 and a plurality of bit lines BL extending in the second direction D2 and apart from one another in the first direction D1. In some embodiments, the first direction D1 and the second direction D2 may be horizontal directions orthogonal to each other. However, embodiments are not limited thereto. For example, one of the first direction D1 and the second direction D2 may be a vertical direction, and the other may be a horizontal direction.

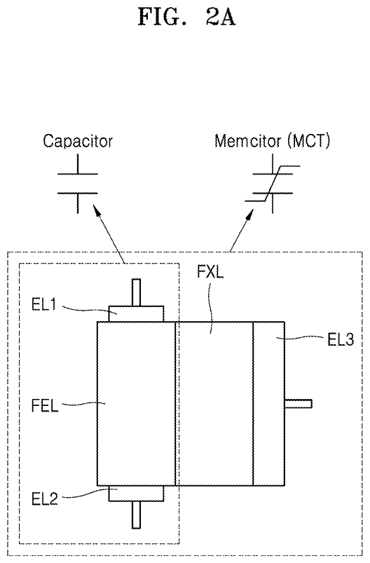

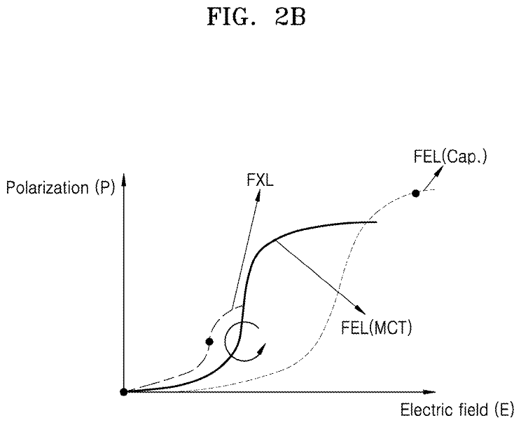

A plurality of memory cells MC may be arranged between the plurality of word lines WL and the plurality of bit lines BL. For example, each of the plurality of memory cells MC may be arranged at an intersection of one of the plurality of word lines WL and one of the plurality of bit lines BL. Each of the plurality of memory cells MC may include a cell transistor CT and a memcitor MCT. The cell transistor CT may select the memory cell MC, and information may be stored in the memcitor MCT. The cell transistor CT may be serially connected to the memcitor MCT. The memcitor MCT may include a first electrode EL1, a second electrode EL2, and a third electrode EL3. A configuration of the memcitor MCT will be described in detail with reference to FIG. 2A. In some embodiments, a gate of the cell transistor CT may be connected to a word line WL, a source of the cell transistor CT may be connected to a bit line BL, and a drain of the cell transistor CT may be connected to the second electrode EL2 of the memcitor MCT.

FIGS. 2A and 2B are views describing a configuration and operating principle of a memcitor MCT included in a memory cell of a semiconductor device according to an embodiment.

Referring to FIG. 2A, the memcitor MCT includes an information storage layer FEL, a fixed layer FXL stacked on the information storage layer FEL, the first electrode EL1 and the second electrode EL2 connected to both ends of the information storage layer FEL, and the third electrode EL3 connected to the fixed layer FXL. The memcitor MCT may be referred to as an information storage element.

The information storage layer FEL may include a dielectric material. The fixed layer FXL may include a dielectric material. The third electrode EL3 may be connected to a part of the fixed layer FXL, which does not contact the information storage layer FEL. The first electrode EL1 and the second electrode EL2 may not contact the fixed layer FXL, and the third electrode EL3 may not contact the information storage layer FEL. The fixed layer FXL may be interposed between the information storage layer FEL and the third electrode EL3. For example, the first electrode EL1 may be arranged on a top surface of the information storage layer FEL, the second electrode EL2 may be arranged on a bottom surface of the information storage layer FEL, and the fixed layer FXL may be arranged on a side of the information storage layer FEL. The third electrode EL3 may be arranged on a side of the fixed layer FXL, which is opposite to a side on which the information storage layer FEL is arranged. For example, the information storage layer FEL and the fixed layer FXL may be arranged on opposite sides of the fixed layer FXL, respectively.

The information storage layer FEL may include a material with ferroelectricity, that is, a ferroelectric material. The fixed layer FXL may include a material with paraelectricity or a material with antiferroelectricity, for example, a paraelectric material or an antiferroelectric material. For example, each of the information storage layer FEL and the fixed layer FXL may include one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, and barium-doped titanium oxide. In some embodiments, the information storage layer FEL may include hafnium oxide (HfO₂), and the fixed layer FXL may include zirconium oxide (ZrO₂).

Each of the first electrode EL1, the second electrode EL2, and the third electrode EL3 may include a metal material. For example, each of the first electrode EL1, the second electrode EL2, and the third electrode EL3 may include at least one of a metal, metal nitride, conductive metal oxide, metal carbide, and metal silicide. In some embodiments, each of the first electrode EL1, the second electrode EL2, and the third electrode EL3 may include tungsten (W), aluminum (Al), copper (Cu), titanium (Ti), tantalum (Ta), titanium nitride (TiN), tantalum nitride (TaN), tungsten nitride (WN), tungsten carbonitride, or a combination thereof.

In some embodiments, the information storage layer FEL may include a ferroelectric material with an orthorhombic phase. In some embodiments, the fixed layer FXL may include a paraelectric material or an antiferroelectric material with a tetragonal phase.

For example, the ferroelectric material included in the information storage layer FEL may have various crystalline phases. The information storage layer FEL may include a ferroelectric material having an orthorhombic phase dominant thickness. In some embodiments, the information storage layer FEL may have a stacked structure including a plurality of layers sequentially arranged between the first electrode EL1 and the second electrode EL2, for example, a plurality of sub-information storage layers. In some embodiments, each of the plurality of layers forming the information storage layer FEL may include a ferroelectric material. For example, each of the plurality of ferroelectric layers included in the information storage layer FEL may have an orthorhombic phase dominant thickness. In other embodiments, at least one of the plurality of layers forming the information storage layer FEL may include a ferroelectric material, and at least one other layer may include a paraelectric material or an antiferroelectric material.

For example, the paraelectric material or the antiferroelectric material included in the fixed layer FXL may have various crystalline phases. The fixed layer FXL may include a paraelectric material or an antiferroelectric material having a tetragonal phase dominant thickness.

The first electrode EL1, the second electrode EL2, and the information storage layer FEL between the first electrode EL1 and the second electrode EL2 may form a capacitor. The first electrode EL1 and the second electrode EL2 may be an upper electrode and a lower electrode of the capacitor. The first electrode EL1, the second electrode EL2, and the information storage layer FEL forming the capacitor, and the fixed layer FXL and the third electrode EL3 may form the memcitor MCT.

A memcitor or a memcitance device may be obtained by combining a non-volatile memory function with a capacitor (volatile) to change polarization or charge by applying an electric field. Memcitors (memcitance devices) combine a capacitor (volatile) with memory functions that change their polarizations or charges by applying an electric field in, for example, a nonvolatile manner.)

Referring to FIGS. 2A and 2B together, polarization P may occur in each of the information storage layer FEL and the fixed layer FXL when an electric field E is applied to each of the information storage layer FEL and the fixed layer FXL. In some embodiments, a direction of polarization occurring in the information storage layer FEL may be different from a direction of polarization occurring in the fixed layer FXL. A sufficiently large polarization P may occur in the information storage layer FEL only when a large electric field E is applied to the information storage layer FEL Polarization P that is greater than polarization occurring in the information storage layer FEL may occur in the fixed layer FXL even though a small electric field E is applied to the fixed layer FXL.

When the electric field E is applied to each of the information storage layer FEL and the fixed layer FXL stacked on the information storage layer FEL, which are included in the memcitor MCT, the polarization P may occur in the information storage layer FEL even though a small electric field E is applied to the information storage layer FEL due to the polarization P occurring in the fixed layer FXL. That is, even though a small electric field E is applied, larger polarization P may occur in the memcitor MCT including in the information storage layer FEL and the fixed layer FXL stacked on the information storage layer FEL than in a capacitor that includes the information storage layer FEL.

In addition, a magnitude of the polarization P occurring in the information storage layer FEL may vary depending on strength of the electric field E applied to the fixed layer FXL in the memcitor MCT. That is, the strength of the electric field E to be applied to the information storage layer FEL in order to generate the polarization P in the information storage layer FEL may vary depending on the strength of the electric field E applied to the fixed layer FXL in the memcitor MCT.

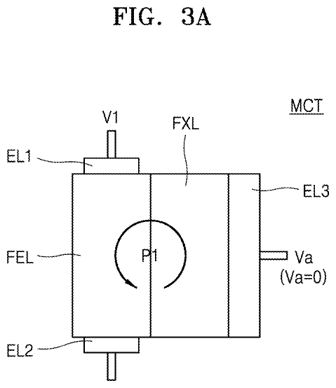

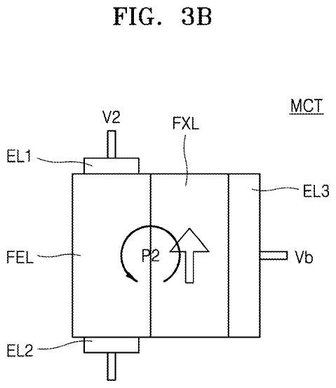

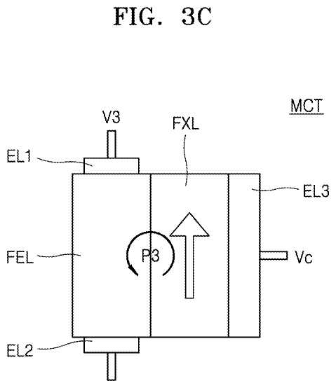

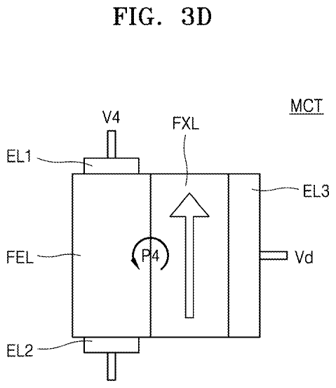

FIGS. 3A to 3D are views describing an operation of a memcitor included in a memory cell of a semiconductor device according to an embodiment.

Referring to FIGS. 3A to 3D, when a first boosting voltage Va and Va=0 is applied to the third electrode EL3, that is, the third electrode EL3 connected to the fixed layer FXL, polarization may not occur in the fixed layer FXL. In this case, first fixed polarization P1 may occur in the information storage layer FEL due to an electric field caused by a first voltage V1 applied between the first electrode EL1 and the second electrode EL2. The first voltage V1 may have a large value. That is, when the first boosting voltage Va and Va=0 is applied to the third electrode EL3, that is, when the electric field is not applied to the third electrode EL3, large first fixed polarization P1 may occur in the information storage layer FEL when a large electric field is applied to the information storage layer FEL.

When a small second boosting voltage Vb and Vb>Va is applied to the third electrode EL3 connected to the fixed layer FXL, small polarization may occur in the fixed layer FXL. In this case, second fixed polarization P2 may occur in the information storage layer FEL due to an electric field caused by a second voltage V2 applied between the first electrode EL1 and the second electrode EL2. The second voltage V2 may have a value less than that of the first voltage V1. That is, when the second boosting voltage Vb and Vb>Va is applied to the third electrode EL3, such as, when a small electric field is applied to the third electrode EL3, the second fixed polarization P2 less than the first fixed polarization P1 may occur in the information storage layer FEL even though the second voltage V2, less than the first voltage V1, is applied to the information storage layer FEL.

When a third boosting voltage Vc and Vc>Vb is applied to the third electrode EL3 connected to the fixed layer FXL, larger polarization may occur in the fixed layer FXL than that which occurs in the fixed layer FXL when the second boosting voltage Vb is applied to the third electrode EL3. In this case, third fixed polarization P3 may occur in the information storage layer FEL due to an electric field resulting from a third voltage V3 being applied between the first electrode EL1 and the second electrode EL2. The third voltage V3 may have a value less than that of the second voltage V2. That is, when the third boosting voltage Vc and Vc>Vb is applied to the third electrode EL3, the third fixed polarization P3 less than the second fixed polarization P2 may occur in the information storage layer FEL even though the third voltage V3, which less than the second voltage V2, is applied to the information storage layer FEL.

When a fourth boosting voltage Vd and Vd>Vc is applied to the third electrode EL3 connected to the fixed layer FXL, larger polarization may occur in the fixed layer FXL than that which occurs in the fixed layer FXL when the third boosting voltage Vc is applied to the third electrode EL3. In this case, a fourth fixed polarization P4 may occur in the information storage layer FEL due to an electric field resulting from a fourth voltage V4 being applied between the first electrode EL1 and the second electrode EL2. The fourth voltage V4 may have a value less than that of the third voltage V3. That is, when the fourth boosting voltage Vd and Vd>Vc is applied to a fourth electrode EL4, a fourth fixed polarization P4 that is less than the third fixed polarization P3 may occur in the information storage layer FEL even though the fourth voltage V4, which is less than the third voltage V3, is applied to the information storage layer FEL.

The terms ‘first fixed polarization P1’ ‘second fixed polarization P2’, ‘third fixed polarization P3’, and ‘fourth fixed polarization P4’ occurring in the information storage layer FEL may refer to polarization that occurs in the information storage layer FEL when a voltage is not applied to the information storage layer FEL. The electric field is not applied to the information storage layer FEL after the first voltage V1, the second voltage V2, the third voltage V3, and the fourth voltage V4 are applied to the information storage layer FEL. The electric field may then be applied to the first voltage V1, the second voltage V2, the third voltage V3, and the fourth voltage V4. In the current specification, the term ‘fixed polarization’ refers to polarization that is maintained even though an electric field is not applied, and polarization occurs when an electric field is applied. The fixed polarization may be spontaneous polarization of a ferroelectric material.

The first voltage V1, the second voltage V2, the third voltage V3, and the fourth voltage V4 may be equal to or greater than a threshold voltage in which zero electric field polarization, that is, the first fixed polarization P1, the second fixed polarization P2, the third fixed polarization P3, and the fourth fixed polarization P4 may occur even when the electric field applied to the information storage layer FEL is removed due to the electric field generated by the voltage applied to the information storage layer FEL when the first boosting voltage Va, the second boosting voltage Vb, the third boosting voltage Vc, and the fourth boosting voltage Vd are applied to the fixed layer FXL.

The larger the voltage applied to the fixed layer FXL, the smaller the voltage that may generate fixed polarization in the information storage layer FEL. The larger the voltage applied to the fixed layer FXL, the smaller the fixed polarization occurring in the information storage layer FEL. The smaller the voltage applied to the fixed layer FXL, the larger the voltage that may generate fixed polarization in the information storage layer FEL. The smaller the voltage applied to the fixed layer FXL, the larger the fixed polarization occurring in the information storage layer FEL. That is, the magnitude of the voltage that may generate the fixed polarization in the information storage layer FEL and the magnitude of the fixed polarization occurring in the information storage layer FEL may be inversely proportional to that of the voltage applied to the fixed layer FXL.

When a large voltage is applied to the fixed layer FXL, since the magnitude of the voltage that can generate the fixed polarization in the information storage layer FEL may be reduced, the operating power of a semiconductor device including a plurality of memory cells, each including the memcitor MCT, may be reduced.

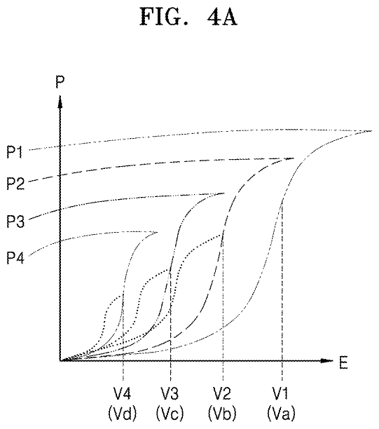

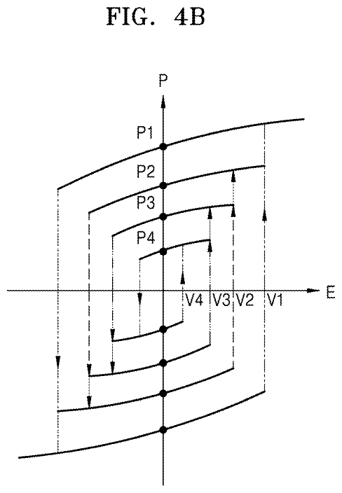

FIGS. 4A and 4B are graphs describing an operation of a memcitor included in a memory cell of a semiconductor device according to an embodiment.

Referring to FIGS. 3A, 3B, 3C, 3D, 4A, and 4B together, when the first voltage V1 is applied to the information storage layer FEL and the first boosting voltage Va is applied to the fixed layer FXL, the first fixed polarization P1 may occur in the information storage layer FEL. When the second voltage V2 is applied to the information storage layer FEL and the second boosting voltage Vb is applied to the fixed layer FXL, the second fixed polarization P2 may occur in the information storage layer FEL. When the third voltage V3 is applied to the information storage layer FEL and the third boosting voltage Vc is applied to the fixed layer FXL, the third fixed polarization P3 may occur in the information storage layer FEL. When the fourth voltage V4 is applied to the information storage layer FEL and the fourth boosting voltage Vd is applied to the fixed layer FXL, the fourth fixed polarization P4 may occur in the information storage layer FEL. That is, because a magnitude of the fixed polarization that may occur in the information storage layer FEL varies depending on the voltage applied to the fixed layer FXL, depending on the voltage applied to the fixed layer FXL and the voltage applied to the information storage layer FEL, a multi-level bit may be stored in the memcitor MCT including the information storage layer FEL and the fixed layer FXL.

Therefore, a semiconductor device including a plurality of memory cells each including the memcitor MCT may store a large amount of information.

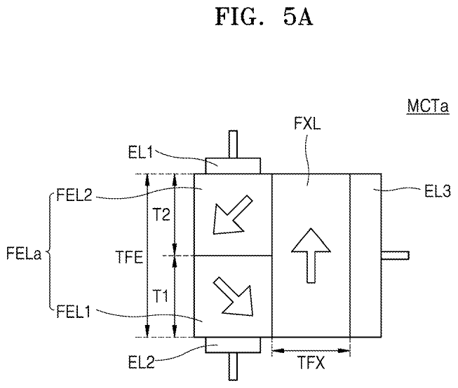

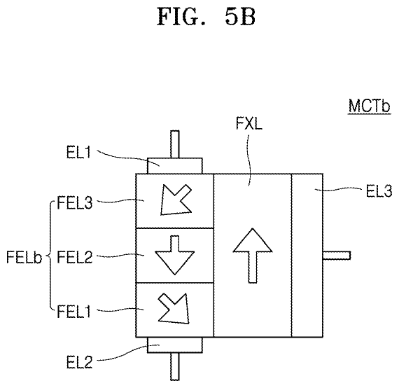

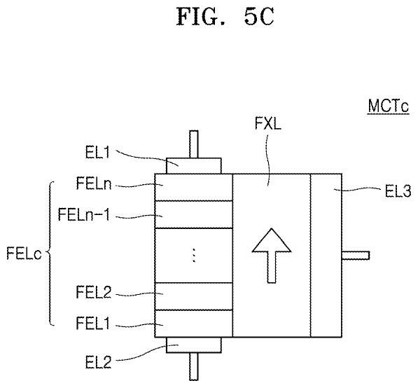

FIGS. 5A to 5C are views describing configurations of memcitors MCTa, MCTb, and MCTc included in memory cells of a semiconductor device according to embodiments.

Referring to FIG. 5A, the memcitor MCTa may include an information storage layer FELa, a fixed layer FXL stacked on the information storage layer FELa, a first electrode EL1 and a second electrode EL2 connected to both ends of the information storage layer FELa, and a third electrode EL3 connected to the fixed layer FXL.

The information storage layer FELa may have a stacked structure including a first sub-information storage layer FEL1 and a second sub-information storage layer FEL2. For example, the memcitor MCTa may include the first sub-information storage layer FEL1 on the second electrode EL2, the second sub-information storage layer FEL2 on the first sub-information storage layer FEL1, the first electrode EL1 on the second sub-information storage layer FEL2, the fixed layer FXL stacked on the first sub-information storage layer FEL1 and the second sub-information storage layer FEL2, and the third electrode EL3 connected to the fixed layer FXL. It is illustrated in FIG. 5A that the fixed layer FXL contacts both the first sub-information storage layer FEL1 and the second sub-information storage layer FEL2. However, embodiments are not limited thereto. The fixed layer FXL may contact the information storage layer FELa in which the first sub-information storage layer FEL1 and the second sub-information storage layer FEL2 form a stacked structure, and may not contact the first electrode EL1 and the second electrode EL2. For example, the fixed layer FXL may contact the first sub-information storage layer FEL1 and may not contact the second sub-information storage layer FEL2. For example, the fixed layer FXL may not contact the first sub-information storage layer FEL1 and instead may contact the second sub-information storage layer FEL2. In some embodiments, the fixed layer FXL may contact both the first sub-information storage layer FEL1 and the second sub-information storage layer FEL2.

In some embodiments, each of the first sub-information storage layer FEL1 and the second sub-information storage layer FEL2 may include a ferroelectric material. In other embodiments, one of the first sub-information storage layer (FEL1 or FEL2) and the second sub-information storage layer FEL2 may include a ferroelectric material, and the other one of the sub-information storage layer (FEL1 or FEL2) may include a paraelectric material or an antiferroelectric material.

The information storage layer FELa may have a first thickness TFE in a direction between the first electrode EL1 and the second electrode EL2. The fixed layer FXL may have a second thickness TFX and may be stacked on the information storage layer FELa. That is, the second thickness TFX of the fixed layer FXL may be the thickness of the fixed layer FXL in a direction perpendicular to a surface of the information storage layer FELa, that contacts the fixed layer FXL. The first sub-information storage layer FEL1 and the second sub-information storage layer FEL2 may have a first sub-thickness T1 and a second sub-thickness T2, respectively, in the direction between the first electrode EL1 and the second electrode EL2. The first thickness TFE may be about 10 Å to about 100 Å, and the second thickness TFX may be about 5 Å to about 50 Å. Each of the first sub-thickness T1 and the second sub-thickness T2 may be about 5 Å to about 50 Å.

Directions of fixed polarizations occurring in the first sub-information storage layer FEL1 and the second sub-information storage layer FEL2 may be different from a direction of polarization occurring in the fixed layer FXL. Fixed polarizations in different directions may occur in the first sub-information storage layer FEL1 and the second sub-information storage layer FEL2. For example, when a voltage is applied to the fixed layer FXL so that upward polarization occurs in the fixed layer FXL, downward fixed polarizations may occur in the first sub-information storage layer FEL1 and the second sub-information storage layer FEL2 in diagonal directions different from each other. For example, when a voltage is applied to the fixed layer FXL so that polarization occurs in the fixed layer FXL in a 12 o'clock direction, fixed polarization may occur in the first sub-information storage layer FEL1 in a direction of about 3:30 to about 5:30, and fixed polarization may occur in the second sub-information storage layer FEL2 in a direction of about 7:30 to about 8:30. On the same plane, for example, on a plane formed by a direction in which the first sub-information storage layer FEL1 and the second sub-information storage layer FEL2 are stacked, and a direction in which the information storage layer FELa and the fixed layer FXL are stacked, the polarization may occur in the fixed layer FXL clockwise or counterclockwise, the fixed polarization may occur in the first sub-information storage layer FEL1 clockwise or counterclockwise, and the fixed polarization may occur in the second sub-information storage layer FEL2 clockwise or counterclockwise.

Therefore, when the polarization occurs in the fixed layer FXL, although a low voltage is applied to the information storage layer FELa such that a small electric field is generated, the fixed polarizations may occur in the first sub-information storage layer FEL1 and the second sub-information storage layer FEL2 within a short time.

Referring to FIG. 5B, the memcitor MCTb may include an information storage layer FELb, a fixed layer FXL stacked on the information storage layer FELb, a first electrode EL1 and a second electrode EL2 connected to both ends of the information storage layer FELb, and a third electrode EL3 connected to the fixed layer FXL.

The information storage layer FELb may have a stacked structure including the first sub-information storage layer FEL1 and the second sub-information storage layer FEL2. For example, the memcitor MCTb may include the first sub-information storage layer FEL1 on the second electrode EL2, the second sub-information storage layer FEL2 on the first sub-information storage layer FEL1, a third sub-information storage layer FEL3 on the second sub-information storage layer FEL2, the first electrode EL1 on the third sub-information storage layer FEL3, the fixed layer FXL stacked on the first sub-information storage layer FEL1, the second sub-information storage layer FEL2, and the third sub-information storage layer FEL3, and the third electrode EL3 connected to the fixed layer FXL.

In some embodiments, each of the first sub-information storage layer FEL1, the second sub-information storage layer FEL2, and the third sub-information storage layer FEL3 may include a ferroelectric material. In other embodiments, at least one of the first sub-information storage layer FEL1, the second sub-information storage layer FEL2, and the third sub-information storage layer FEL3 may include a ferroelectric material, and at least one other sub-information storage layer may include a paraelectric material or an antiferroelectric material.

Fixed polarizations may occur in the first sub-information storage layer FEL1, the second sub-information storage layer FEL2, and the third sub-information storage layer FEL3 in different directions. On the same plane, for example, on a plane formed by a direction in which the first sub-information storage layer FEL1, the second sub-information storage layer FEL2, and the third sub-information storage layer FEL3 are stacked and a direction in which the information storage layer FELb and the fixed layer FXL are stacked, the polarization may occur in the fixed layer FXL clockwise or counterclockwise, the fixed polarization may occur in the first sub-information storage layer FEL1 clockwise or counterclockwise. The fixed polarization may occur in the second sub-information storage layer FEL2 clockwise or counterclockwise, and the fixed polarization may occur in the third sub-information storage layer FEL3 clockwise or counterclockwise.

Therefore, when the polarization occurs in the fixed layer FXL, although a low voltage is applied to the information storage layer FELb so that a small electric field is generated, the fixed polarizations may occur in the first sub-information storage layer FEL1, the second sub-information storage layer FEL2, and the third sub-information storage layer FEL3 within a short time.

Referring to FIG. 5C, the memcitor MCTc may include an information storage layer FELc, a fixed layer FXL stacked on the information storage layer FELc, a first electrode EL1 and a second electrode EL2 connected to both ends of the information storage layer FELc, and a third electrode EL3 connected to the fixed layer FXL.

The information storage layer FELc may have a stacked structure including first to nth sub-information storage layers FEL1, FEL2, . . . , FELn−1, and FELn. For example, the information storage layer FELc included in the memcitor MCTc may have a stacked structure in which the first to nth sub-information storage layers FEL1, FEL2, . . . , FELn−1, and FELn are sequentially arranged between the second electrode EL2 and the first electrode EL1.

In some embodiments, each of the first to nth sub-information storage layers FEL1, FEL2, . . . , FELn−1, and FELn may include a ferroelectric material. In other embodiments, at least one of the first to nth sub-information storage layers FEL1, FEL2, . . . , FELn−1, and FELn may include a ferroelectric material and at least one other sub-information storage layer may include a paraelectric material or an antiferroelectric material.

Fixed polarizations may occur in the first to nth sub-information storage layers FEL1, FEL2, . . . , FELn−1, and FELn included in the information storage layer FELc in directions different from a direction in which polarization may occur in the fixed layer FXL. In some embodiments, the fixed polarizations may occur in the first to nth sub-information storage layers FEL1, FEL2, . . . , FELn−1, and FELn included in the information storage layer FELc in the same direction, for example, in a direction opposite to the direction in which the polarization may occur in the fixed layer FXL. In other embodiments, at least some of the fixed polarizations occurring in the first to nth sub-information storage layers FEL1, FEL2, . . . , FELn−1, and FELn included in the information storage layer FELc may face directions different from directions the others of the sub-information storage layers face, on the same plane, for example, on a plane formed by a direction in which the first to nth sub-information storage layers FEL1, FEL2, . . . , FELn−1, and FELn are stacked and a direction in which the information storage layer FELc and the fixed layer FXL are stacked, polarization may occur in the fixed layer FXL in a clockwise or counterclockwise direction and the fixed polarizations may occur in the first to nth sub-information storage layers FEL1, FEL2, . . . , FELn−1, and FELn in clockwise or counterclockwise directions.

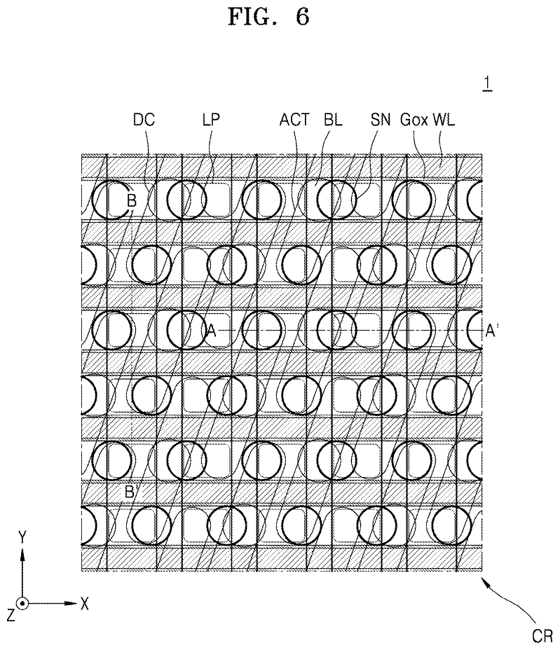

FIG. 6 is a schematic plan layout describing main components of a semiconductor device 1 according to an embodiment.

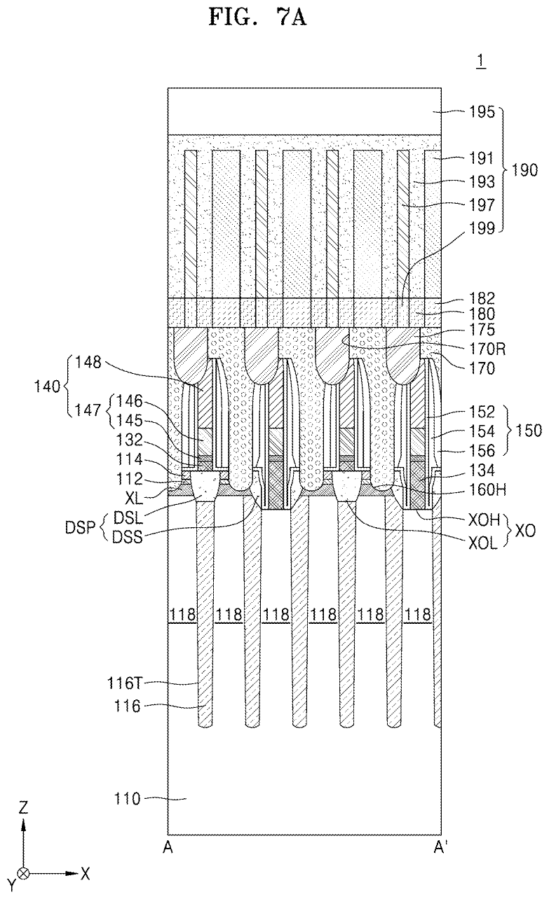

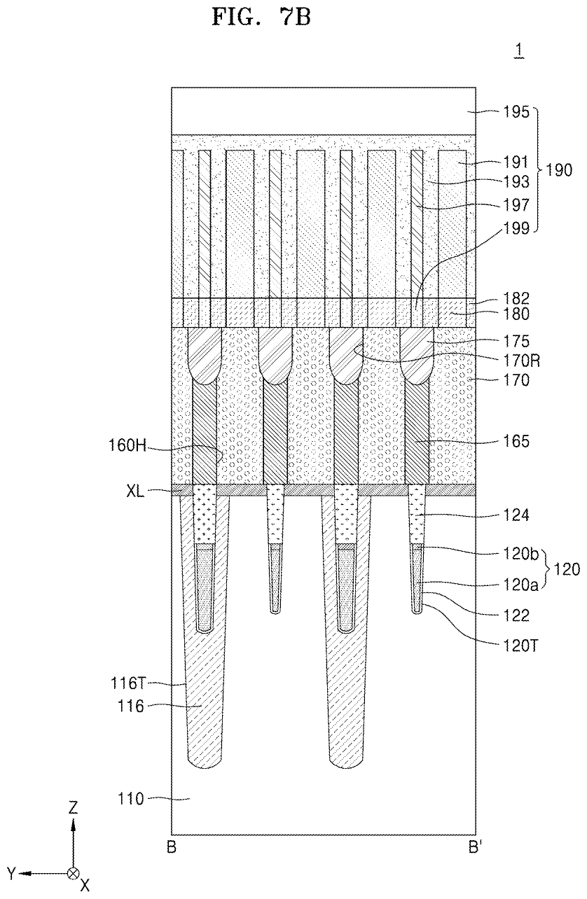

Referring to FIG. 6, the semiconductor device 1 may include a plurality of active regions ACT formed in a memory cell region CR. In some embodiments, the active regions ACT may be arranged in the memory cell region CR to have long axes in a diagonal direction with respect to a first horizontal direction (an X direction) and a second horizontal direction (a Y direction) orthogonal to each other. The active regions ACT may constitute a plurality of active regions 118 illustrated in FIG. 7A.

A plurality of word lines WL may extend parallel to one another in the first horizontal direction (the X direction) across the active regions ACT. A plurality of gate dielectric layers Gox may be interposed between the active regions ACT and the word lines WL. In some embodiments, the gate dielectric layers Gox may extend parallel to one another along the first horizontal direction (the X direction) to cover sides and bottoms of the word lines WL.

The plurality of bit lines BL may extend on the plurality of word lines WL parallel to one another along the second horizontal direction (the Y direction) intersecting the first horizontal direction (the X direction). Each of a plurality of landing pads LP may extend from between each two adjacent bit lines of the plurality of bit lines BL to an upper portion of one of each two adjacent bit lines of the plurality of bit lines BL. In some embodiments, the landing pads LP may be arranged in a line in the first horizontal direction (the X direction) and the second horizontal direction (the Y direction).

A plurality of storage nodes SN may be formed on the plurality of landing pads LP. The storage nodes SN may be formed on the bit lines BL. The storage nodes SN may be lower electrodes of a plurality of capacitors, that is, second electrodes of a plurality of memcitors. The storage nodes SN may be connected to the active regions ACT through the landing pads LP, respectively.

FIGS. 7A and 7B are cross-sectional views illustrating the semiconductor device 1 according to an embodiment. Specifically, FIGS. 7A and 7B are cross-sectional views taken along the lines A-A′ and B-B′ of FIG. 6.

Referring to FIGS. 7A and 7B together, the semiconductor device 1 may include a plurality of active regions 118 defined by a plurality of device isolation layers 116, a substrate 110 having a plurality of word line trenches 120T crossing the plurality of active regions 118, a plurality of word lines 120 arranged in the plurality of word line trenches 120T, a plurality of bit line structures 140, and a plurality of memcitors 190.

The substrate 110 may include, for example, silicon (Si), crystalline Si, polycrystalline Si, or amorphous Si. In other embodiments, the substrate 110 may include a semiconductor element such as germanium (Ge), or at least one compound semiconductor selected from silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide (BOX) layer. The substrate 110 may include a conductive region, for example, an impurity-doped well or an impurity-doped structure.

The active regions 118 may be parts of the substrate 110 limited by device isolation trenches 116T. The active regions 118 may be in the form of long islands having short axes and long axes in a plan view. In some embodiments, the active regions 118 may be arranged to have long axes in a diagonal direction with respect to the first horizontal direction (the X direction) and the second horizontal direction (the Y direction). The active regions 118 may extend along a long axis direction to have substantially the same length and may be repeatedly arranged with a constant pitch. The active regions 118 may constitute the plurality of active regions ACT illustrated in FIG. 6.

The device isolation layers 116 may fill the device isolation trenches 116T. The active regions 118 may be defined in the substrate 110 by the plurality of device isolation layers 116.

In some embodiments, each of the device isolation layers 116 may include a triple layer including a first device isolation layer, a second device isolation layer, and a third device isolation layer. However, embodiments are not limited thereto. As an example, the first device isolation layer may conformally cover an internal surface and a bottom surface of each of the device isolation trenches 116T. For example, the second device isolation layer may conformally cover the first device isolation layer. For example, the third device isolation layer may cover the second device isolation layer and may fill each of the device isolation trenches 116T. In some embodiments, each of the plurality of device isolation layers 116 may include a single layer including one type of insulating layer, a double layer including two types of insulating layers, or a multilayer including a combination of at least four types of insulating layers.

A plurality of cell pad patterns XL may be arranged on the plurality of device isolation layers 116 and the plurality of active regions 118. In some embodiments, a pair of cell pad patterns XL may be arranged apart from each other on one active region 118. For example, the pair of cell pad patterns XL apart from each other may be arranged on both sides of the active region 118 in the long axis direction. A conductive layer may cover the device isolation layers 116 and the active regions 118. The cell pad patterns XL may include Si, Ge, W, WN, cobalt (Co), nickel (Ni), Al, molybdenum (Mo), ruthenium (Ru), Ti, TiN, Ta, TaN, Cu, or a combination thereof. For example, the cell pad patterns XL may include polysilicon.

The word line trenches 120T may be formed in the substrate 110 including the plurality of active regions 118 defined by the plurality of device isolation layers 116 and the plurality of cell pad patterns XL. The word line trenches 120T may be in the form of lines extending parallel to one another in the first horizontal direction (the X direction), crossing the active regions 118, and arranged at substantially equal intervals along the second horizontal direction (the Y direction). In some embodiments, a step may be formed on a bottom surface of each of the plurality of word line trenches 120T.

A plurality of gate dielectric layers 122, a plurality of word lines 120, and a plurality of buried insulating layers 124 may be sequentially formed in the word line trenches 120T. The word lines 120 may constitute the plurality of word lines WL illustrated in FIG. 6. The word lines 120 may be in the form of lines extending parallel to one another in the first horizontal direction (the X direction), crossing the active regions 118, and arranged at substantially equal intervals along the second horizontal direction (the Y direction). A top surface of each of the plurality of word lines 120 may be at a vertical level lower than that of a top surface of the substrate 110. A bottom surface of each of the plurality of word lines 120 may be concavo-convex shaped, and a saddle fin field effect transistor (FET) may be formed in each of the plurality of active regions 118.

In the current specification, a level or a vertical level means a height in a direction (a Z direction) perpendicular to a main surface or the top surface of the substrate 110. That is, being at the same level or a constant level means that heights from the main surface or top surface of the substrate 110 in the vertical direction (the Z direction) are the same or constant, and being at a low/high vertical level means that a height from the main surface of the substrate 110 in the vertical direction (the Z direction) is low/high.

The word lines 120 may fill lower parts of the word line trenches 120T. Each of the word lines 120 may have a stacked structure of a lower word line layer 120a and an upper word line layer 120b. For example, each of the lower word line layers 120a may conformally cover an internal wall and a bottom surface of the lower part of each of the word line trenches 120T with each of the gate dielectric layers 122 between each of the lower word line layers 120a and each of the word line trenches 120T. For example, each of the plurality of upper word line layers 120b may cover each of the plurality of lower word line layers 120a and may fill the lower part of each of the plurality of word line trenches 120T with each of the plurality of gate dielectric layers 122 between each of the upper word line layers 120b and each of the word line trenches 120T. In some embodiments, the lower word line layers 120a may include a metal material or conductive metal nitride such as Ti, TiN, Ta, or TaN. In some embodiments, the plurality of upper word line layers 120b may include, for example, doped polysilicon, a metal material such as W, conductive metal nitride such as WN, TiSiN, or WSiN, or a combination thereof.

A source region and a drain region formed by implanting impurity ions into each of the plurality of active regions 118 may be arranged in each of the active regions 118 of the substrate 110 on both sides of each of the word lines 120.

Each of the plurality of gate dielectric layers 122 may cover the internal wall and bottom surface of each of the plurality of word line trenches 120T. The plurality of gate dielectric layers 122 may constitute the plurality of gate dielectric layers Gox illustrated in FIG. 6. In some embodiments, each of the plurality of gate dielectric layers 122 may extend from between each of the plurality of word lines 120 and each of the plurality of word line trenches 120T to between the buried insulating layer 124 and each of the plurality of word line trenches 120T. The plurality of gate dielectric layers 122 may include at least one selected from silicon oxide, silicon nitride, silicon oxynitride, oxide/nitride/oxide (ONO), and a high-k dielectric material having a dielectric constant higher than that of silicon oxide. For example, each of the plurality of gate dielectric layers 122 may have a dielectric constant of about 10 to about 25. In some embodiments, the plurality of gate dielectric layers 122 may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the plurality of gate dielectric layers 122 may include HfO₂, Al₂O₃, HfAlO₃, Ta₂O₃, or TiO₂.

The plurality of buried insulating layers 124 may cover the plurality of word lines 120 and may fill upper parts of the plurality of word line trenches 120T. Therefore, the plurality of buried insulating layers 124 may extend parallel to one another in the first horizontal direction (the X direction). In some embodiments, a top surface of each of the plurality of buried insulating layers 124 may be at substantially the same vertical level as that of a top surface of each of the plurality of cell pad patterns XL. Each of the plurality of buried insulating layers 124 may include at least one material layer selected from silicon oxide, silicon nitride, silicon oxynitride, and a combination thereof. For example, the plurality of buried insulating layers 124 may include silicon nitride.

The plurality of cell pad patterns XL may be arranged in a matrix in the first horizontal direction (the X direction) and the second horizontal direction (the Y direction). The plurality of cell pad patterns XL may be isolated and insulated from one another by the plurality of buried insulating layers 124 extending in the first horizontal direction (the X direction) and a plurality of isolation insulation patterns DSP filling at least parts of a plurality of isolation trenches XO extending in the second horizontal direction (the Y direction). The plurality of isolation trenches XO may extend among the plurality of cell pad patterns XL in the second horizontal direction (the Y direction).

A plurality of insulating layer patterns may be arranged on the plurality of cell pad patterns XL and the plurality of buried insulating layers 124. In some embodiments, each of the plurality of insulating layer patterns may have a stacked structure including a first insulating layer pattern 112 and a second insulating layer pattern 114. In some embodiments, the second insulating layer pattern 114 may be thicker than the first insulating layer pattern 112. For example, the first insulating layer pattern 112 may have a thickness of about 50 Å to about 90 Å, and the second insulating layer pattern 114 may be thicker than the first insulating layer pattern 112, and may have a thickness of about 60 Å to about 100 Å.

In each of the plurality of isolation trenches XO, a line trench XOL having a line shape extending in the second horizontal direction (the Y direction) in a plan view and a hole trench XOH having a circular shape in a plan view may be connected to each other and may alternate with each other in the second horizontal direction (the Y direction). The plurality of device isolation layers 116, the plurality of active regions 118, and the plurality of buried insulating layers 124 may be exposed to bottom surfaces of the plurality of isolation trenches XO.

Each of the plurality of active regions 118 may be exposed to a bottom surface of each of the plurality of hole trenches XOH more than each of the plurality of device isolation layers 116 and each of the plurality of buried insulating layers 124. Each of the plurality of cell pad patterns XL, each of the plurality of first insulating layer patterns 112, and each of the plurality of second insulating layer patterns 114 may be exposed to side walls of each of the plurality of isolation trenches XO. In the first horizontal direction (the X direction), a width of the hole trench XOH may be greater than that of the line trench XOL. In some embodiments, the bottom surface of the hole trench XOH may be at a vertical level lower than that of a bottom surface of the line trench XOL. That is, a depth of the hole trench XOH may be greater than that of the line trench XOL in each of the plurality of isolation trenches XO.

Each of the plurality of isolation insulation patterns DSP may include an isolation insulation line DSL filling the line trench XOL and an isolation insulation spacer DSS covering a side wall of the hole trench XOH. In each of the plurality of isolation insulation patterns DSP, the isolation insulation line DSL having a line shape extending in the second horizontal direction (the Y direction) in a plan view and the isolation insulation spacer DSS having a ring shape extending in the second horizontal direction (the Y direction) in a plan view may be connected to each other and may alternate with each other in the second horizontal direction (the Y direction). In the first horizontal direction (the X direction), a width of an outer edge of each of the plurality of isolation insulation spacers DSS may be greater than that of each of the plurality of isolation insulation lines DSL. Each of the plurality of isolation insulation lines DSL may be connected to and integrated with each of the plurality of isolation insulation spacers DSS. In some embodiments, a top surface of the isolation insulation pattern DSP may be at the same vertical level as that of a top surface of the second insulating layer pattern 114 and may be coplanar with the top surface of the second insulating layer pattern 114.

Each of the plurality of isolation insulation lines DSL may be interposed between each two cell pad patterns adjacent in the first horizontal direction (the X direction) among the plurality of cell pad patterns XL and may isolate and insulate each two adjacent cell pad patterns from each other. The isolation insulation spacer DSS may cover each of the plurality of cell pad patterns XL, each of the plurality of first insulating layer patterns 112, and each of the plurality of second insulating layer patterns 114 exposed to the side walls of each of the plurality of isolation trenches XO. The isolation insulation spacer DSS may surround a lower part of a direct contact conductive pattern 134 in the hole trench XOH to isolate and insulate the direct contact conductive pattern 134 from a neighboring cell pad pattern XL. On the side wall of the hole trench XOH, the isolation insulation spacer DSS may have a thickness equal to or greater than ½ of the width of the line trench XOL and less than ½ of the width of the hole trench XOH in the first horizontal direction (the X direction).

In some embodiments, the plurality of isolation insulation patterns DSP may be formed by an extreme ultraviolet (EUV) lithography process. For example, the plurality of isolation trenches XO may be formed by an etching process using a mask pattern formed by an EUV lithography process as an etching mask, and the plurality of isolation insulation patterns DSP may be formed to fill at least parts of the plurality of isolation trenches XO. Each of the plurality of isolation insulation lines DSL and each of the plurality of isolation insulation spacers DSS included in each of the plurality of isolation insulation patterns DSP may be formed by a single EUV lithography process without using a photolithography process.

In a plan view, both sides of the cell pad pattern XL in the second horizontal direction (the Y direction) may be linear to contact the buried insulating layer 124 and to extend in the first horizontal direction (the X direction). In a plan view, one of both sides of each of the plurality of cell pad patterns XL may contact each of the plurality of isolation insulation lines DSL in the first horizontal direction (the X direction) and may extend in the second horizontal direction (the Y direction) and the other may be arc shaped to contact each of the plurality of isolation insulation spacers DSS and to be concave into each of the plurality of cell pad patterns XL.

Each of a plurality of direct contact conductive patterns 134 may fill a part of the hole trench XOH exposing the source region in the active region 118 through the second insulating layer pattern 114 and the first insulating layer pattern 112. In some embodiments, the hole trench XOH may extend into the active region 118, that is, the source region. The plurality of direct contact conductive patterns 134 may include, for example, doped polysilicon. In some embodiments, each of the plurality of direct contact conductive patterns 134 may include an epitaxial silicon layer. The plurality of direct contact conductive patterns 134 may constitute a plurality of direct contacts DC illustrated in FIG. 6.

The plurality of bit line structures 140 may be arranged on the second insulating layer pattern 114. Each of the plurality of bit line structures 140 may include a bit line 147 and an insulation capping line 148 covering the bit line 147. The plurality of bit line structures 140 may extend parallel to one another in the second horizontal direction (the Y direction) parallel to the main surface of the substrate 110. The plurality of bit lines 147 may constitute the plurality of bit lines BL illustrated in FIG. 6. The plurality of bit lines 147 may be electrically connected to the plurality of active regions 118 through the plurality of direct contact conductive patterns 134, respectively. In some embodiments, the bit line structure 140 may further include a conductive semiconductor pattern 132 between the second insulating layer pattern 114 and the bit line 147. The conductive semiconductor pattern 132 may include, for example, doped polysilicon.

The plurality of isolation insulation patterns DSP may extend in the second horizontal direction (the Y direction) along bottoms of the plurality of bit lines 147 and the plurality of bit line structures 140 including the same. At least parts of the plurality of isolation insulation patterns DSP and the plurality of bit lines 147 or the plurality of isolation insulation patterns DSP and the plurality of bit line structures 140 may overlap in the vertical direction (the Z direction).

The plurality of cell pad patterns XL may be arranged on the plurality of active regions 118 with each of the plurality of bit line structures 140 including the plurality of bit lines 147 between each two adjacent cell pad patterns. The plurality of cell pad patterns XL may be arranged on the plurality of active regions 118 with each of the plurality of word lines 120 between each two adjacent cell pad patterns. That is, the plurality of cell pad patterns XL may be arranged in a matrix with each of the plurality of word lines 120 between each two adjacent cell pad patterns on the plurality of active regions 118 in the first horizontal direction (the X direction), and with each of the plurality of bit line structures 140 between each two adjacent cell pad patterns on the plurality of active regions 118 in the second horizontal direction (the Y direction).

The bit line 147 may have a stacked structure of a first metallic conductive pattern 145 and a second metallic conductive pattern 146 in the form of lines. In some embodiments, the first metallic conductive pattern 145 may include TiN or Ti—Si—N(TSN), and the second metallic conductive pattern 146 may include W, or tungsten and tungsten silicide (WSiₓ). In some embodiments, the first metallic conductive pattern 145 may function as a diffusion barrier. In some embodiments, a plurality of insulation capping lines 148 may include silicon nitride.

Each of a plurality of insulation spacer structures 150 may cover both side walls of each of the plurality of bit line structures 140. Each of the plurality of insulation spacer structures 150 may include a first insulation spacer 152, a second insulation spacer 154, and a third insulation spacer 156. In some embodiments, each of the plurality of insulation spacer structures 150 may extend into each of the plurality of hole trenches XOH to cover both side walls of each of the plurality of direct contact conductive patterns 134. The second insulation spacer 154 may include a material with a dielectric constant lower than that of the first insulation spacer 152 and the third insulation spacer 156. In some embodiments, the first insulation spacer 152 and the third insulation spacer 156 may include nitride, and the second insulation spacer 154 may include oxide. In some embodiments, the first insulation spacer 152 and the third insulation spacer 156 may include nitride, and the second insulation spacer 154 may include a material having etch selectivity with respect to the first insulation spacer 152 and the third insulation spacer 156. For example, the first insulation spacer 152 and the third insulation spacer 156 may include nitride, and the second insulation spacer 154 may include an air spacer. In some embodiments, each of the plurality of insulation spacer structures 150 may include the second insulation spacer 154 including oxide and the third insulation spacer 156 including nitride.

Each of a plurality of insulation fences 165 may be interposed between a pair of insulation spacer structures 150 facing each other between a pair of neighboring bit line structures 140. The plurality of insulation fences 165 may be apart from one another in a column along a pair of insulation spacer structures 150 facing each other, that is, in the second horizontal direction (the Y direction). For example, the plurality of insulation fences 165 may include nitride.

In some embodiments, the plurality of insulation fences 165 may extend into the plurality of buried insulating layers 124 through the plurality of second insulating layer patterns 114 and the plurality of first insulating layer patterns 112. However, embodiments are not limited thereto. In other embodiments, the plurality of insulation fences 165 may pass through the plurality of second insulating layer patterns 114 and the plurality of first insulating layer patterns 112 and may not extend into the plurality of buried insulating layers 124, may extend into the plurality of second insulating layer patterns 114 without passing through the plurality of first insulating layer patterns 112, or may pass through the plurality of second insulating layer patterns 114 and may extend into the plurality of first insulating layer patterns 112 without passing through the plurality of first insulating layer patterns 112. Alternatively, the plurality of insulation fences 165 may be formed so that bottom surfaces of the plurality of insulation fences 165 may contact top surfaces of the plurality of second insulating layer patterns 114 without extending into the plurality of second insulating layer patterns 114.

Among the plurality of bit lines 147, a plurality of contact holes 160H may be limited among the plurality of insulation fences 165. Along a pair of insulation spacer structures 150 facing each other among the plurality of insulation spacer structures 150 each covering both side walls of each of the plurality of bit line structures 140, that is, in the second horizontal direction (the Y direction), each of the plurality of contact holes 160H and each of the plurality of insulation fences 165 may alternate with each other. An internal space of each of the plurality of contact holes 160H may be limited by each of the plurality of insulation spacer structures 150 covering side walls of each of two neighboring bit lines 147 between two neighboring bit lines 147 among the plurality of bit lines 147, each of the plurality of insulation fences 165, and each of the plurality of cell pad patterns XL. In some embodiments, each of the plurality of contact holes 160H may extend from between each of the plurality of insulation spacer structures 150 and each of the plurality of insulation fences 165 into each of the plurality of cell pad patterns XL on each of the plurality of active regions 118.

A plurality of landing pads 170 may fill the plurality of contact holes 160H to contact the plurality of cell pad patterns XL and may extend onto the plurality of bit line structures 140. The plurality of landing pads 170 may be isolated from one another with a recess 170R between each two adjacent landing pads. Each of the plurality of landing pads 170 may include a conductive barrier layer and a conductive pad material layer on the conductive barrier layer. For example, the conductive barrier layer may include a metal, conductive metal nitride, or a combination thereof. In some embodiments, the conductive barrier layer may have a stacked structure of Ti/TiN. In some embodiments, the conductive pad material layer may include W. In some embodiments, a metal silicide layer may be formed between each of the plurality of landing pads 170 and each of the plurality of cell pad patterns XL. The metal silicide layer may include cobalt silicide (CoSiₓ), nickel silicide (NiSiₓ), or manganese silicide (MnSiₓ). However, embodiments are not limited thereto.

The plurality of landing pads 170 may be connected to the plurality of active regions 118 through the plurality of cell pad patterns XL, respectively. The plurality of landing pads 170 may constitute the plurality of landing pads LP illustrated in FIG. 6.

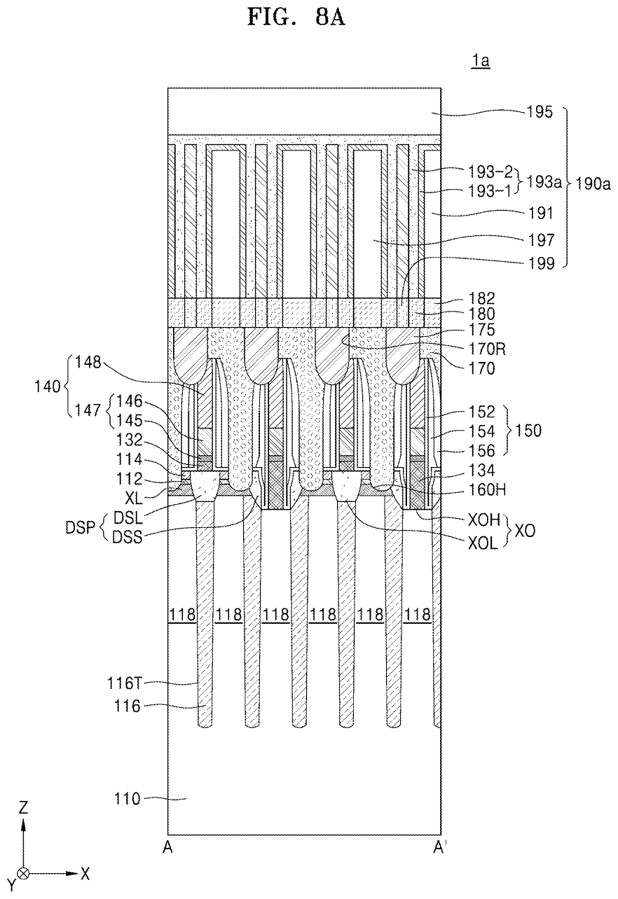

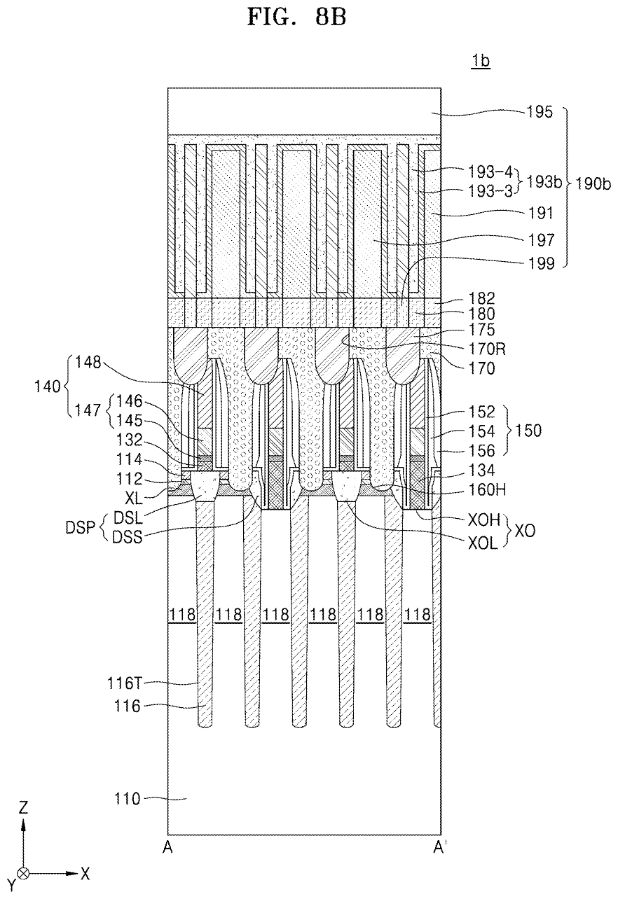

The recess 170R may be filled with an insulation structure 175. In some embodiments, the insulation structure 175 may include an interlayer insulating layer and an etching stop layer. For example, the interlayer insulating layer may include oxide, and the etching stop layer may include nitride. It is illustrated in FIGS. 8A and 8B that top surfaces of the plurality of insulation structures 175 are at the same vertical level as that of top surfaces of the plurality of landing pads 170. However, embodiments are not limited thereto. For example, the top surfaces of the plurality of insulation structures 175 may be at a vertical level higher than that of the top surfaces of the plurality of landing pads 170 by filling the plurality of recesses 170R and covering the top surfaces of the plurality of landing pads 170.

In some embodiments, a plurality of capacitor pads 182 and a plurality of etching stop layers 180 surrounding the plurality of capacitor pads 182 may be arranged on the plurality of landing pads 170 and the plurality of insulation structures 175. The plurality of capacitor pads 182 may contact the plurality of landing pads 170, respectively. The plurality of landing pads 170 may be electrically connected to the plurality of capacitor pads 182, respectively.

A plurality of capacitor structures including a plurality of lower electrodes 191, a capacitor dielectric layer 193, and an upper electrode 195 may be arranged on the plurality of capacitor pads 182 and the plurality of etching stop layers 180. The plurality of lower electrodes 191 may contact the plurality of capacitor pads 182, respectively. The plurality of lower electrodes 191 may be electrically connected to the plurality of capacitor pads 182, respectively. In some embodiments, the plurality of capacitor pads 182 and the plurality of etching stop layers 180 may be omitted, the plurality of capacitor structures including the plurality of lower electrodes 191, the capacitor dielectric layer 193, and the upper electrode 195 may be arranged on the plurality of landing pads 170 and the insulation structure 175, and the plurality of lower electrodes 191 may contact the plurality of landing pads 170, respectively.

The capacitor dielectric layer 193 may conformally cover surfaces of the plurality of lower electrodes 191. In some embodiments, the capacitor dielectric layer 193 may be integrally formed in a constant region, for example, a cell block, to cover the surfaces of the plurality of lower electrodes 191. The plurality of lower electrodes 191 may constitute the plurality of storage nodes SN illustrated in FIG. 6.

Each of the plurality of lower electrodes 191 may be in the form of a pillar, the inside of which is filled to have a circular horizontal cross-section. However, embodiments are not limited thereto. In some embodiments, each of the plurality of lower electrodes 191 may be in the form of a cylinder. The bottom of which bottom is closed. In some embodiments, the plurality of lower electrodes 191 may be arranged in zigzags in the first horizontal direction (the X direction) or the second horizontal direction (the Y direction). In other embodiments, the plurality of lower electrodes 191 may be arranged in a matrix in the first horizontal direction (the X direction) and the second horizontal direction (the Y direction). The plurality of lower electrodes 191 may include impurity-doped silicon, a metal such as W or Co, or a conductive metal compound such as titanium nitride.

The capacitor dielectric layer 193 may include a ferroelectric material. For example, the capacitor dielectric layer 193 may include one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, and barium-doped titanium oxide. In some embodiments, the capacitor dielectric layer 193 may include hafnium oxide (HfO₂).

The upper electrode 195 may include W, Al, Cu, Ti, Ta, TiN, TaN, WN, tungsten carbonitride, or a combination thereof.

A plurality of fixed layers 197 may be arranged on the plurality of etching stop layers 180, and a plurality of fixed layer electrodes 199 electrically connected to the plurality of fixed layers 197 may be arranged in the plurality of etching stop layers 180. The plurality of fixed layers 197 may contact the capacitor dielectric layer 193. For example, the capacitor dielectric layer 193 may be interposed between the plurality of fixed layers 197 and the plurality of lower electrodes 191.

The plurality of lower electrodes 191, the capacitor dielectric layer 193, the upper electrode 195, the plurality of fixed layers 197, and the plurality of fixed layer electrodes 199 may constitute the plurality of memcitors 190. The upper electrode 195, the capacitor dielectric layer 193, the plurality of lower electrodes 191, the plurality of fixed layers 197, and the plurality of fixed layer electrodes 199 may include the first electrode EL1, the information storage layers FEL, FELa, and FELb, the second electrode EL2, the fixed layer FXL, and the third electrode EL3 described with reference to FIGS. 1 to 5B. Each of the plurality of active regions 118, each of the plurality of word lines 120, and each of the plurality of gate dielectric layers 122 may constitute a cell transistor. The plurality of cell transistors and the plurality of memcitors 190 included in the semiconductor device 1 may be arranged in the vertical direction (the Z direction).

FIGS. 8A and 8B are cross-sectional views illustrating a semiconductor device 1a according to an embodiment. Specifically, FIGS. 8A and 8B are cross-sectional views taken along a portion corresponding to the line A-A′ of FIG. 6. In FIGS. 8A and 8B, description previously given with reference to FIGS. 7A and 7B will not be repeated.

Referring to FIG. 8A, the semiconductor device 1a includes a plurality of active regions 118 defined by a plurality of device isolation layers 116, a substrate 110 having a plurality of word line trenches 120T crossing the plurality of active regions 118, a plurality of word lines 120 arranged in the plurality of word line trenches 120T, a plurality of bit line structures 140, and a plurality of memcitors 190a.

The plurality of memcitors 190a may include a plurality of lower electrodes 191, a capacitor dielectric layer 193a, an upper electrode 195, a plurality of fixed layers 197, and a plurality of fixed layer electrodes 199. The capacitor dielectric layer 193a may have a stacked structure including a first capacitor dielectric layer 193-1 and a second capacitor dielectric layer 193-2. For example, the first capacitor dielectric layer 193-1 and the second capacitor dielectric layer 193-2 may constitute the first sub-information storage layer FEL1 and the second sub-information storage layer FEL2 illustrated in FIG. 5A.

The first capacitor dielectric layer 193-1 and the second capacitor dielectric layer 193-2 may be sequentially stacked on the plurality of lower electrodes 191. In some embodiments, the second capacitor dielectric layer 193-2 may be interposed between the first capacitor dielectric layer 193-1 and the plurality of fixed layers 197. The plurality of fixed layers 197 may contact the second capacitor dielectric layer 193-2, and may not directly contact the first capacitor dielectric layer 193-1.

Referring to FIG. 8B, the semiconductor device 1b includes a plurality of active regions 118 defined by a plurality of device isolation layers 116, a substrate 110 having a plurality of word line trenches 120T crossing the plurality of active regions 118, a plurality of word lines 120 arranged in the plurality of word line trenches 120T, a plurality of bit line structures 140, and a plurality of memcitors 190b.

The plurality of memcitors 190b may include a plurality of lower electrodes 191, a capacitor dielectric layer 193b, an upper electrode 195, a plurality of fixed layers 197, and a plurality of fixed layer electrodes 199. The capacitor dielectric layer 193b may have a stacked structure including a first capacitor dielectric layer 193-3 and a second capacitor dielectric layer 193-4. For example, the first capacitor dielectric layer 193-3 and the second capacitor dielectric layer 193-4 may be the first sub-information storage layer FEL1 and the second sub-information storage layer FEL2 illustrated in FIG. 5A.

The first capacitor dielectric layer 193-3 and the second capacitor dielectric layer 193-4 may be sequentially stacked on the plurality of lower electrodes 191. In some embodiments, the second capacitor dielectric layer 193-4 may be interposed between the first capacitor dielectric layer 193-3 and the plurality of fixed layers 197. The plurality of fixed layers 197 may contact both the first capacitor dielectric layer 193-3 and the second capacitor dielectric layer 193-4. For example, the first capacitor dielectric layer 193-3 may conformally cover the plurality of lower electrodes 191 and the plurality of etching stop layers 180 and the second capacitor dielectric layer 193-4 may cover the first capacitor dielectric layer 193-3. The plurality of fixed layers 197 may extend from the plurality of fixed layer electrodes 199 into the second capacitor dielectric layer 193-4 through the first capacitor dielectric layer 193-3.

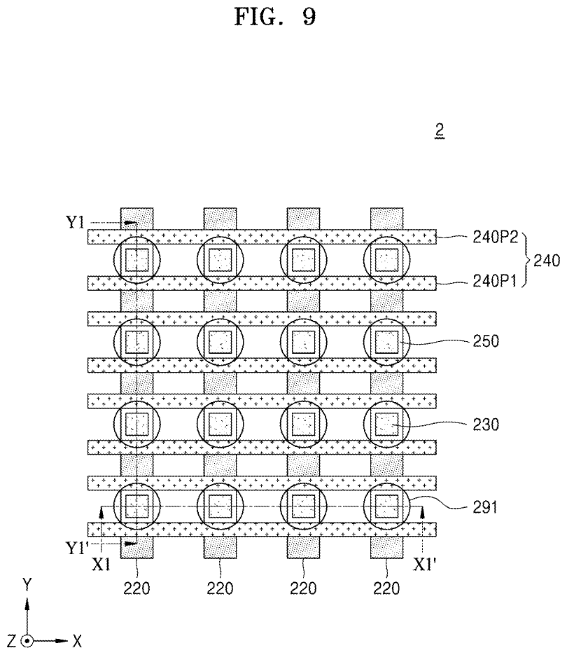

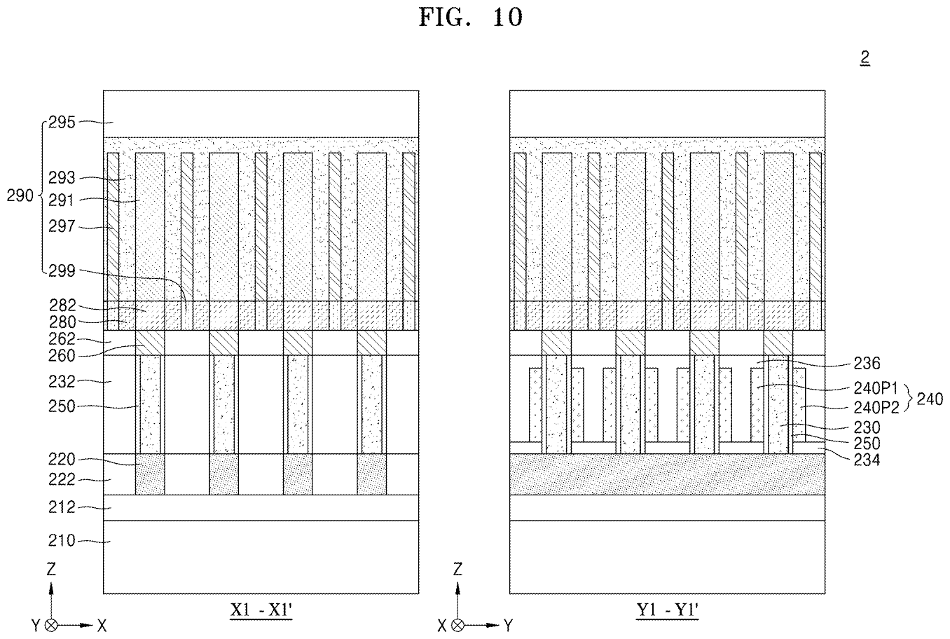

FIG. 9 is a layout diagram illustrating a semiconductor device 2 according to an embodiment, and FIG. 10 is a cross-sectional view taken along the lines X1-X1′ and Y1-Y1′ of FIG. 9.

Referring to FIGS. 9 and 10, the semiconductor device 2 may include a substrate 210, a plurality of first conductive lines 220, a plurality of channel layers 230, a plurality of gate electrodes 240, a plurality of gate insulating layers 250, and a plurality of memcitors 290. The semiconductor device 2 may include a memory device including a vertical channel transistor (VCT). The VCT may refer to a structure in which a channel length of each of the plurality of channel layers 230 extends from the substrate 210 in a vertical direction.

A lower insulating layer 212 may be on the substrate 210, and on the lower insulating layer 212. The plurality of first conductive lines 220 may be apart from one another in the first horizontal direction (the X direction) and may extend in the second horizontal direction (the Y direction). A plurality of first insulating patterns 222 may be arranged on the lower insulating layer 212 to fill spaces among the plurality of first conductive lines 220. The first insulating patterns 222 may extend in the second horizontal direction (the Y direction), and a top surface of each of the first insulating patterns 222 may be at the same level as that of a top surface of each of the plurality of first conductive lines 220. The plurality of first conductive lines 220 may function as a plurality of bit lines of the semiconductor device 2.

In embodiments, the plurality of first conductive lines 220 may include doped polysilicon, a metal, conductive metal nitride, conductive metal silicide, conductive metal oxide, or a combination thereof. For example, the plurality of first conductive lines 220 may include doped polysilicon, Al, Cu, Ti, Ta, Ru, W, Mo, platinum (Pt), Ni, Co, TiN, TaN, WN, niobium nitride (NbN), TiAl, TiAlN, TiSi, TiSiN, TaSi, TaSiN, RuTiN, NiSi, CoSi, IrOₓ, RuOₓ, or a combination thereof, as non-limiting examples. Each of the plurality of first conductive lines 220 may include a single layer or a multilayer of the above-described materials. In embodiments, the plurality of first conductive lines 220 may include a two-dimensional semiconductor material. The two-dimensional semiconductor material may include graphene, carbon nanotube, or a combination thereof.

The plurality of channel layers 230 may be arranged in a matrix to be apart from one another on the plurality of first conductive lines 220 in the first horizontal direction (the X direction) and the second horizontal direction (the Y direction). Each of the plurality of channel layers 230 may have a first width in the first horizontal direction (the X direction) and a first height in the vertical direction (the Z direction). The first height may be greater than the first width. For example, the first height may be about 2 to 10 times the first width, as non-limiting examples. A bottom of each of the plurality of channel layers 230 may function as a first source/drain region (not shown), an upper portion of each of the plurality of channel layers 230 may function as a second source/drain region (not shown), and a part of each of the plurality of channel layers 230 between the first and second source/drain regions may function as a channel region (not shown).

In embodiments, each of the plurality of channel layers 230 may include an oxide semiconductor and, for example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrxZnySnzO, SnxO, HfxInyZnzO, GaxZnySnzO, AlₓZn_{y}Sn_{z}O, YbₓGa_{y}Zn_{z}O, InₓGa_{y}O, or a combination thereof. Each of the plurality of channel layers 230 may include a single layer or a multilayer of the oxide semiconductor. In some examples, each of the plurality of channel layers 230 may have bandgap energy greater than that of silicon. For example, each of the plurality of channel layers 230 may have bandgap energy of about 1.5 eV to about 5.6 eV. For example, each of the plurality of channel layers 230 may have optimal channel performance when each of the plurality of channel layers 230 has bandgap energy of about 2.0 eV to about 4.0 eV. For example, the plurality of channel layers 230 may be polycrystalline or amorphous, as non-limiting examples. In embodiments, the plurality of channel layers 230 may include a two-dimensional semiconductor material. The two-dimensional semiconductor material may include, for example, graphene, carbon nanotube, or a combination thereof.

Each of the plurality of gate electrodes 240 may extend on first and second side walls of each of the plurality of channel layers 230 in the first horizontal direction (the X direction). Each of the plurality of gate electrodes 240 may include a first sub-gate electrode 240P1 facing the first side wall of each of the plurality of channel layers 230 and a second sub-gate electrode 240P2 facing the second side wall opposite the first side wall of each of the plurality of channel layers 230. When each of the plurality of channel layers 230 is arranged between each of the plurality of first sub-gate electrodes 240P1 and each of the plurality of second sub-gate electrodes 240P2, the semiconductor device 2 may have a dual-gate transistor structure, as non-limiting examples. In some implementations, the second sub-gate electrode 240P2 may be omitted and only the first sub-gate electrode 240P1 facing the first side wall of the channel layer 230 may be formed, such that a single-gate transistor structure may be implemented.

The plurality of gate electrodes 240 may include doped polysilicon, a metal, conductive metal nitride, conductive metal silicide, conductive metal oxide, or a combination thereof. For example, the plurality of gate electrodes 240 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, as non-limiting examples.

Each of the plurality of gate insulating layers 250 may surround the side walls of each of the plurality of channel layers 230 and may be interposed between each of the plurality of channel layers 230 and each of the plurality of gate electrodes 240. For example, as illustrated in FIG. 9, all the side walls of each of the plurality of channel layers 230 may be surrounded by each of the plurality of gate insulating layers 250, and parts of each of the plurality of gate electrodes 240 may contact each of the plurality of gate insulating layers 250. In other embodiments, each of the plurality of gate insulating layers 250 may extend in a direction (that is, the first horizontal direction (the X direction)) in which each of the plurality of gate electrodes 240 extends and only two side walls facing each of the plurality of gate electrodes 240 among the side walls of each of the plurality of channel layers 230 may contact each of the plurality of gate insulating layers 250.

In embodiments, each of the plurality of gate insulating layers 250 may include a silicon oxide layer, a silicon oxynitride layer, a high-k dielectric layer having a dielectric constant higher than that of the silicon oxide layer, or a combination thereof. The high-k dielectric layer may include metal oxide or metal oxynitride. For example, the high-k dielectric layer that may be used as each of the plurality of gate insulating layers 250 may include HfO₂, HfSiO, HfSiON, HfTaO, HfTiO, HfZrO, ZrO₂, Al₂O₃, or a combination thereof, as non-limiting examples.

Referring to FIG. 10, a plurality of second insulating patterns 232 may extend on the plurality of first insulating patterns 222 in the second horizontal direction (the Y direction), and each of the plurality of channel layers 230 may be arranged between each two adjacent second insulating patterns of the plurality of second insulating patterns 232. In addition, between each two adjacent second insulating patterns of the plurality of second insulating patterns 232, each of a plurality of first buried layers 234 and each of a plurality of second buried layers 236 may be arranged in a space between each two adjacent channel layers of the plurality of channel layers 230. Each of the plurality of first buried layers 234 may be arranged on a bottom of the space between each two adjacent channel layers of the plurality of channel layers 230 and each of the plurality of second buried layers 236 may fill a remaining part of the space between each two adjacent channel layers of the plurality of channel layers 230 on each of the plurality of first buried layers 234. A top surface of each of the plurality of second buried layers 236 may be at the same level as a top surface of each of the plurality of channel layers 230. Each of the plurality of second buried layers 236 may cover a top surface of each of the plurality of gate electrodes 240. Each of the plurality of second insulating patterns 232 may include a material layer that is continuous to each of the plurality of first insulating patterns 222. Each of the plurality of second buried layers 236 may include a material layer that is continuous to each of the plurality of first buried layers 234.

A plurality of capacitor contacts 260 may be arranged on the plurality of channel layers 230, respectively. The capacitor contacts 260 may vertically overlap the plurality of channel layers 230, respectively, and may be arranged in a matrix to be apart from one another in the first horizontal direction (the X direction) and the second horizontal direction (the Y direction). The capacitor contacts 260 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, as non-limiting examples. An upper insulating layer 262 may surround side walls of the capacitor contacts 260 on the plurality of second insulating patterns 232 and the plurality of second buried layers 236.

A plurality of capacitor pads 282 and a plurality of etching stop layers 280 surrounding the plurality of capacitor pads 282 may be arranged on the upper insulating layer 262. A plurality of capacitor structures including a plurality of lower electrodes 291, a capacitor dielectric layer 293, and an upper electrode 295 may be arranged on the capacitor pads 282 and the etching stop layers 280.

The plurality of lower electrodes 291 may contact the plurality of capacitor pads 282, respectively. The plurality of lower electrodes 291 may be electrically connected to the plurality of capacitor pads 282, respectively. In some embodiments, the capacitor pads 282 and etching stop layers 280 may be omitted. The plurality of capacitor structures including the lower electrodes 291, the capacitor dielectric layer 293, and the upper electrode 295 may be arranged on the capacitor contacts 260 and the upper insulating layer 262. The plurality of lower electrodes 291 may contact the plurality of capacitor contacts 260, respectively.

A plurality of fixed layers 297 may be arranged on the etching stop layers 280. A plurality of fixed layer electrodes 299 electrically connected to the fixed layers 297 may be arranged in the etching stop layers 280. The fixed layers 297 may contact the capacitor dielectric layer 293. For example, the capacitor dielectric layer 293 may be interposed between the fixed layers 297 and the f lower electrodes 291.

The lower electrodes 291, the capacitor dielectric layer 293, the upper electrode 295, the plurality of fixed layers 297, and the fixed layer electrodes 299 may constitute the memcitors 290. The upper electrode 295, the capacitor dielectric layer 293, the f lower electrodes 291, the fixed layers 297, and the fixed layer electrodes 299 may include the first electrode EL1, the information storage layers FEL, FELa, and FELb, the second electrode EL2, the fixed layer FXL, and the third electrode EL3 as described with reference to FIGS. 1 to 5B. Each of the plurality of channel layers 230, each of the gate electrodes 240, and each of the gate insulating layers 250 may constitute a cell transistor. The cell transistors and the memcitors 290 included in the semiconductor device 2 may be arranged in the vertical direction (the Z direction).

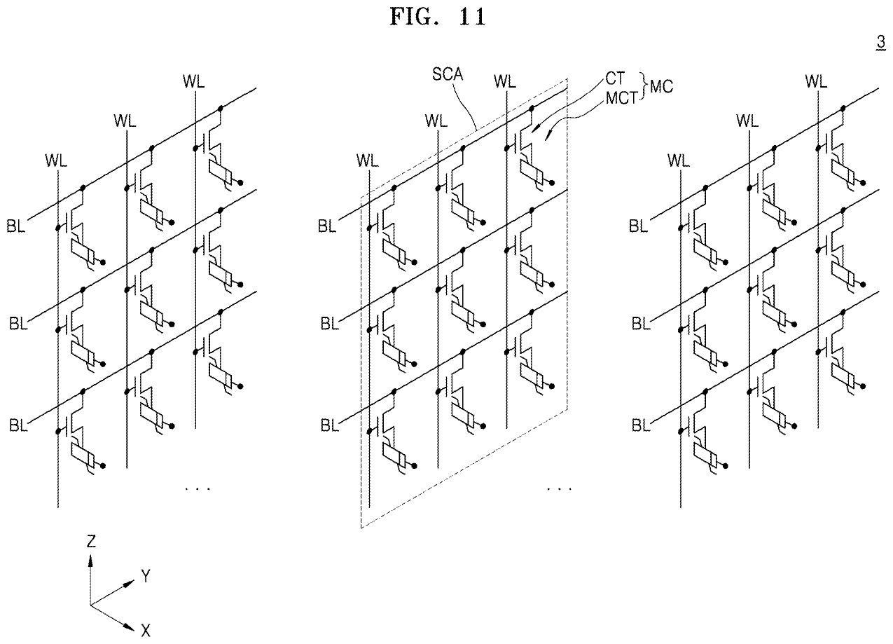

FIG. 11 is an equivalent circuit diagram of a semiconductor device 3 according to an embodiment.

Referring to FIG. 11, the semiconductor device 3 may be a three-dimensional semiconductor device. The semiconductor device 3 may include a plurality of sub-cell arrays SCA. The plurality of sub-cell arrays SCA may be arranged in the first horizontal direction (the X direction).

Each of the plurality of sub-cell arrays SCA may include a plurality of bit lines BL, a plurality of word lines WL, and a plurality of cell transistors CT. Each of the plurality of cell transistors CT may be arranged between each of the plurality of word lines WL and each of the plurality of bit lines BL.

The plurality of bit lines BL may include a plurality of conductive patterns (for example, a plurality of metal lines) apart from a substrate to be arranged above the substrate. The plurality of bit lines BL may extend in the second horizontal direction (the Y direction). The bit lines BL in each of the plurality of sub-cell arrays SCA may be spaced apart from one another in the vertical direction (the Z direction).

The plurality of word lines WL may include a plurality of conductive patterns (for example, a plurality of metal lines) extending from the substrate in the vertical direction (the Z direction). The word lines WL in each of the sub-cell arrays SCA may be spaced apart from one another in the second horizontal direction (the Y direction).

A gate of each of the plurality of cell transistors CT may be connected to each of the plurality of word lines WL. A source of each of the plurality of cell transistors CT may be connected to each of the plurality of bit lines BL. A drain of each of the plurality of cell transistors CT may be connected to each of the plurality of memcitors MCT. Each of the plurality of memcitors MCT may be arranged in the first horizontal direction (the X direction) from each of the plurality of cell transistors CT. Each of the plurality of cell transistors CT and each of the plurality of memcitors MCT may constitute a memory cell MC.

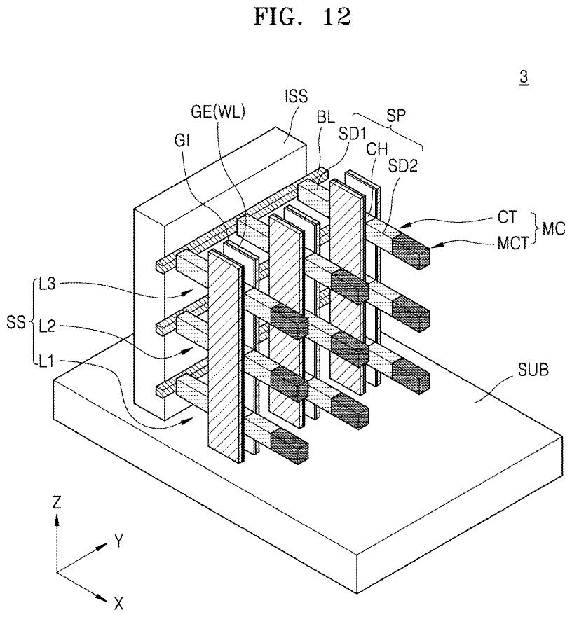

FIG. 12 is a perspective view illustrating the semiconductor device 3 according to an embodiment.

Referring to FIGS. 11 and 12 together, one of the plurality of sub-cell arrays SCA included in the semiconductor device 3 described with reference to FIG. 11 may be provided on a substrate SUB. The substrate SUB may be or include a Si substrate, a Ge substrate, or a SiGe substrate.

For example, a stacked structure SS including first to third layers L1, L2, and L3 may be provided on the substrate SUB. The first to third layers L1, L2, and L3 of the stacked structure SS may be spaced be apart from one another and may be stacked in the vertical direction (the Z direction). Each of the first to third layers L1, L2, and L3 may include a plurality of semiconductor patterns SP, a plurality of memory cells MC, and a bit line BL.

The plurality of semiconductor patterns SP may be in the form of lines, bars, or pillars extending in the first horizontal direction (the X direction). For example, the plurality of semiconductor patterns SP may include Si, Ge, or SiGe. Each of the plurality of semiconductor patterns SP may include a channel region CH, a first impurity region SD1, and a second impurity region SD2. The channel region CH may be interposed between the first impurity region SD1 and the second impurity region SD2. The channel region CH may correspond to a channel of the cell transistor CT described with reference to FIG. 11. The first and second impurity regions SD1 and SD2 may correspond to the source and drain of the cell transistor CT described with reference to FIG. 11.

In each of the plurality of semiconductor patterns SP, the first and second impurity regions SD1 and SD2 may be doped with impurities. Thus, the first and second impurity regions SD1 and SD2 may have n-type or p-type conductivity. The first impurity region SD1 may be formed in an upper portion of each of the plurality of semiconductor patterns SP.

Each of the plurality of memcitors MCT may be connected to one end of each of the plurality of semiconductor patterns SP. The plurality of memcitors MCT may be connected to the plurality of second impurity regions SD2 of the plurality of semiconductor patterns SP, respectively. The memcitor MCT may include the memcitor MCT, MCTa, MCTb, or MCTc described with reference to FIGS. 1 to 5B. The plurality of cell transistors CT and the plurality of memcitors MCT included in the semiconductor device 3 may be arranged in the first horizontal direction (the X direction).

The plurality of bit lines BL may be in the form of lines or bars extending in the second horizontal direction (the Y direction). The bit lines BL may be apart from one another and stacked in the vertical direction (Z direction). The plurality of bit lines BL may include a conductive material. For example, the conductive material may include one of a doped semiconductor material (doped silicon or doped germanium), conductive metal nitride (titanium nitride or tantalum nitride), a metal (W, Ti, or Ta), and a metal-semiconductor compound (tungsten silicide, cobalt silicide, or titanium silicide). The plurality of bit lines BL may include the plurality of bit lines BL described with reference to FIG. 11.

Among the first to third layers L1, L2, and L3, the first layer L1 will be described in detail. The semiconductor patterns SP of the first layer L1 may be apart from one another and stacked in the second horizontal direction (the Y direction). The semiconductor patterns SP of the first layer L1 may be at the same first level. The bit line BL of the first layer L1 may be connected to one end of each of the semiconductor patterns SP of the first layer L1. For example, the bit line BL may be directly connected to the first impurity regions SD1. As another example, the bit line BL may be electrically connected to the first impurity regions SD1 through a metal silicide. A detailed description of the second layer L2 and the third layer L3 may be substantially the same as the previously given description of the first layer L1.

A plurality of gate electrodes GE passing through the stacked structure SS may be provided on the substrate SUB. The plurality of gate electrodes GE may be in the form of lines or pillars extending in the vertical direction (the Z direction). The plurality of gate electrodes GE may be arranged in the second horizontal direction (the Y direction). In a plan view, stacked semiconductor patterns SP may be interposed between a pair of gate electrodes GE. The plurality of gate electrodes GE may vertically extend on side walls of the plurality of vertically stacked semiconductor patterns SP.

For example, among the plurality of gate electrodes GE, the first pair of gate electrodes GE may be adjacent to the first semiconductor pattern SP among the semiconductor patterns SP of the first layer L1, the first semiconductor pattern SP among the semiconductor patterns SP of the second layer L2, and the first semiconductor pattern SP among the semiconductor patterns SP of the third layer L3. Among the plurality of gate electrodes GE, the second pair of gate electrodes GE may be adjacent to the second semiconductor pattern SP among the semiconductor patterns SP of the first layer L1, the second semiconductor pattern SP among the semiconductor patterns SP of the second layer L2, and the second semiconductor pattern SP among the semiconductor patterns SP of the third layer L3.

The plurality of gate electrodes GE may be adjacent to the plurality of channel regions CH of the plurality of semiconductor pattern SP. The plurality of gate electrodes GE may be provided on the side walls of the plurality of channel regions CH and may extend in the vertical direction (the Z direction). A gate insulating layer GI may be interposed between a pair of gate electrodes GE and a channel region CH. The gate insulating layer GI may include one single layer selected from a high-k dielectric layer, a silicon oxide layer, a silicon nitride layer, and a silicon oxynitride layer, or a combination thereof. For example, the high-k dielectric layer may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The plurality of gate electrodes GE may include a conductive material. The conductive material may include one of a doped semiconductor material, conductive metal nitride, a metal, and a metal-semiconductor compound. The plurality of gate electrodes GE may include the plurality of word lines WL described with reference to FIG. 11.

An insulating structure ISS extending in the second horizontal direction (the Y direction) along one side of the stacked structure SS may be provided on the substrate SUB. The other ends of the plurality of semiconductor patterns SP may contact the insulating structure ISS. The insulating structure ISS may include at least one of a silicon oxide layer, a silicon nitride layer, and a silicon oxynitride layer.

Although not shown, empty spaces in the stacked structure SS may be filled with an insulating material. For example, the insulating material may include at least one of a silicon oxide layer, a silicon nitride layer, and a silicon oxynitride layer.

According to the above, embodiments provide a semiconductor device having a plurality of memory cells capable of storing highly integrated and large capacity information.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims

What is claimed is:

1. A semiconductor device comprising a plurality of memory cells each including a cell transistor and a memcitor connected to the cell transistor, wherein:
the memcitor includes an information storage layer including a ferroelectric material, a first electrode and a second electrode connected to both ends of the information storage layer, a fixed layer stacked on the information storage layer and including a paraelectric material or an antiferroelectric material, and a third electrode connected to the fixed layer without contacting the information storage layer.

2. The semiconductor device as claimed in claim 1, wherein the information storage layer has an orthorhombic phase, and
wherein the fixed layer has a tetragonal phase.

3. The semiconductor device as claimed in claim 1, wherein the first electrode and the second electrode are arranged on a top surface and a bottom surface of the information storage layer, respectively, wherein the fixed layer is arranged on a side of the information storage layer, and
wherein the third electrode is arranged on a side of the fixed layer, which is opposite to a side on which the information storage layer is arranged.

4. The semiconductor device as claimed in claim 1, wherein the information storage layer has a stacked structure including a plurality of sub-information storage layers sequentially arranged between the first electrode and the second electrode.

5. The semiconductor device as claimed in claim 4, wherein the fixed layer contacts each of the plurality of sub-information storage layers.

6. The semiconductor device as claimed in claim 4, wherein the fixed layer contacts at least one sub-information storage layer among the plurality of sub-information storage layers, and does not contact at least one other sub-information storage layer.

7. The semiconductor device as claimed in claim 1, further comprising:
a plurality of word lines extending in a first direction and apart from one another in a second direction perpendicular to the first direction; and
a plurality of bit lines extending in the second direction and apart from one another in the first direction, wherein a gate, a source, and a drain of a cell transistor of each of the plurality of memory cells is connected to one of the plurality of word lines, one of the plurality of bit lines, and the second electrode.

8. The semiconductor device as claimed in claim 7, wherein the first direction and the second direction are horizontal directions that are orthogonal to each other.

9. The semiconductor device as claimed in claim 7, wherein the first direction is a vertical direction and the second direction is a horizontal direction.

10. The semiconductor device as claimed in claim 1, wherein a magnitude of a voltage applied between the first electrode and the second electrode to generate fixed polarization in the information storage layer is inversely proportional to that of a voltage applied to the third electrode.

11. The semiconductor device as claimed in claim 10, wherein a magnitude of fixed polarization occurring in the information storage layer is inversely proportional to that of a voltage applied to the third electrode.

12. A semiconductor device comprising:
a substrate;
a plurality of word lines extending on the substrate in a first direction and apart from one another in a second direction perpendicular to the first direction;
a plurality of bit lines extending on the substrate in the second direction and apart from one another in the first direction; and
a plurality of memory cells arranged between the plurality of word lines and the plurality of bit lines and each including a cell transistor and a memcitor connected to the cell transistor,
wherein the memcitor includes:
an information storage layer including a ferroelectric material;
a first electrode and a second electrode connected to both ends of the information storage layer;
a fixed layer that does not contact the first electrode and the second electrode, that is stacked on the information storage layer, and that includes a paraelectric material or an antiferroelectric material; and
a third electrode connected to the fixed layer without contacting the information storage layer.

13. The semiconductor device as claimed in claim 12, wherein the information storage layer comprises a ferroelectric material having an orthorhombic phase dominant thickness, and
wherein the fixed layer comprises a paraelectric material or an antiferroelectric material having a tetragonal phase dominant thickness.

14. The semiconductor device as claimed in claim 12, wherein a direction of polarization occurring in the information storage layer is different from that of polarization occurring in the fixed layer.

15. The semiconductor device as claimed in claim 12, wherein the cell transistor and the memcitor are arranged in a vertical direction.

16. The semiconductor device as claimed in claim 15, wherein a channel layer of the cell transistor has a channel length extending in the vertical direction.

17. The semiconductor device as claimed in claim 12, wherein the first direction is a vertical direction, and the second direction is a first horizontal direction, and
wherein the cell transistor and the memcitor are arranged in a second horizontal direction perpendicular to the first horizontal direction.

18. A semiconductor device comprising:
a substrate;
a plurality of word lines extending on the substrate in a first direction and apart from one another in a second direction perpendicular to the first direction;
a plurality of bit lines extending on the substrate in the second direction and apart from one another in the first direction; and
a plurality of memory cells arranged between the plurality of word lines and the plurality of bit lines and each including a cell transistor and a memcitor connected to the cell transistor, wherein the memcitor includes:
an information storage layer including a ferroelectric material with an orthorhombic phase;
a first electrode and a second electrode connected to both ends of the information storage layer;
a fixed layer that does not contact the first electrode and the second electrode, that is stacked on the information storage layer, and that includes a paraelectric material or an antiferroelectric material with an orthorhombic phase; and
a third electrode connected to the fixed layer without contacting the information storage layer, and
wherein a gate, a source, and a drain of a cell transistor of each of the plurality of memory cells is connected to one of the plurality of word lines, one of the plurality of bit lines, and the second electrode of the memcitor.

19. The semiconductor device as claimed in claim 18, wherein the information storage layer has a stacked structure including a plurality of sub-information storage layers sequentially arranged between the first electrode and the second electrode, and
wherein at least some of the plurality of sub-information storage layers have polarization directions different from those of remaining sub-information storage layers.

20. The semiconductor device as claimed in claim 18, wherein a thickness of the information storage layer is about 10 Å to about 100 Å in a direction between the first electrode and the second electrode, and
wherein a thickness of the fixed layer is about 5 Å to about 50 Å in a direction perpendicular to a surface of the information storage layer, which contacts the fixed layer.
